(19) United States
(12) Patent Application Publication
(10) Pub. No.: US 2021/0167239 A1
(43) Pub. Date: Jun. 3, 2021

(54) Light-Receiving Element

(71) Applicant: Nippon Telegraph and Telephone Corporation, Tokyo (JP)

(72) Inventors: Masahiro Nada, Tokyo (JP); Fumito Nakajima, Tokyo (JP); Hideaki Matsuzaki, Tokyo (JP)

(21) Appl. No.: 17/047,963

(22) PCT Filed: Apr. 9, 2019
(86) PCT No.: PCT/JP2019/015432

§ 371 Date: Oct. 15, 2020

(30) Foreign Application Priority Data
Apr. 19, 2018 (JP) 2018-080427

(51) Int. Cl. H01L 31/105; H01L 31/18; H01L 31/028

(52) U.S. Cl. CPC H01L 31/105; H01L 31/028; H01L 31/1804

(57) ABSTRACT

A light receiving device includes a first semiconductor layer made of a p-type semiconductor formed on a substrate, and a second semiconductor layer made of an n-type semiconductor formed on the substrate. The light receiving device further includes a carrier transit layer made of an undoped semiconductor formed between the first semiconductor layer and the second semiconductor layer, and an n-type light absorbing layer made of an n-type semiconductor formed between the second semiconductor layer and the carrier transit layer. The n-type light absorbing layer has a smaller bandgap energy than other layers.

### CROSS-REFERENCE TO RELATED APPLICATIONS

This application is a national phase entry of PCT Application No. PCT/JP2019/015432, filed on Apr. 9, 2019, which claims priority to Japanese Application No. 2018-080427, filed on Apr. 19, 2018, which applications are hereby incorporated herein by reference.

### TECHNICAL FIELD

The present invention relates to a light receiving device using holes as traveling carriers.

### BACKGROUND

Semiconductor light receiving devices have a role to convert an incident optical signal into an electric signal, and are widely applied to optical receivers in optical communication, photo-mixers for millimeter-wave oscillators, and the like (Non-Patent Literature 1). Conventionally, these semiconductor light receiving devices compatible with optical communication wavelengths have been made of group III-V semiconductors, using InGaAs epitaxially grown on an InP substrate as a light absorbing layer. However, in recent years, with the advancement of a technique of epitaxially growing Ge on a Si substrate, Si/Ge-based, high-speed light receiving devices have been developed.

One of speed limiting factors in the Si/Ge-based light receiving devices is drift saturation velocity of holes in the light absorbing layer. In an operation state of the light receiving devices, since an electric field intensity of the light absorbing layer is constant and therefore the drift saturation velocity of holes can be regarded as constant, in the Si/Ge-based light receiving devices, film thickness of the light absorbing layer can be said to have a linear relationship with a carrier transport time (high speed property).

As a structure for improving the speed performance of such a general Si/Ge-based light receiving device, a “UTC-PD” structure well-known in the InGaAs light absorbing layer can be considered (Non-Patent Literature 1). However, realistically, it is not easy to construct UTC-PD using a Si/Ge-based structure. This is because it is difficult to form a “diffusion barrier layer” indispensable for high-speed and high-sensitivity operation of a UTC-PD in a material system of Si/Ge.

In the case of group III-V semiconductors, presupposing an InP substrate typical in the manufacture of light receiving devices, a wide variety of material systems such as InGaAs, InAlAs, InAlGaAs, and GaAsSb can be selected as a material system that grows in lattice matching with the substrate. However, when considering the Si/Ge-based light receiving device, materials that can grow on the Si substrate are practically limited to Ge and SiGe, but the problem is there is almost no difference in energy at a conduction band edge in any of Si, SiGe, and Ge (Non-Patent Literature 2). For this reason, when the UTC-PD is manufactured using a Si/Ge-based structure, electrons generated in the Ge light absorbing layer diffuse and move in a random direction in the element, and all of the generated electrons do not necessarily move to an n-type layer, causing a decrease in response performance.

In recent years, mixed crystals containing antimony (Sb) have attracted attention as a new material system in the group III-V semiconductors. Sb-based materials can form a Type-II band lineup with respect to InGaAs and InP, and the like even though it is a material system with a relatively narrow gap, so it is a valuable material system in realizing device design utilizing band engineering in the group III-V semiconductors. Furthermore, from the viewpoint of the light receiving device, an APD with low noise can be implemented as compared with typical group III-V semiconductor materials such as InP and GaAs (Non-Patent Literature 3).

However, even if an attempt is made to construct the UTC-PD using Sb-based material in order to improve high-speed performance, this is not easily done. The reason is that it is not possible to form a “diffusion barrier layer” on the band lineup in the same manner as a Si/Ge-based material.

### CITATION LIST

### Non-Patent Literature

Non-Patent Literature 1: T. Ishibashi et al., “Unitraveling-Carrier Photodiodes for Terahertz Applications”, IEEE Journal of Selected Topics in Quantum Electronics, vol. 20, no. 6, pp. 3804210, 2014.

Non-Patent Literature 2: L. Yang et al., “Si/SiGe heterostructure parameters for device simulations”, Semiconductor Science and Technology, vol. 19, pp. 1174-1182, 2004.

Non-Patent Literature 3: M. Ren et al., “Characteristics of AlxIn1-xAsySb1-y (x:0.3-0.7) Avalanche Photodiodes”, Journal of Lightwave Technology, vol. 35, no. 12, pp. 2380-2384, 2017.

Non-Patent Literature 4: B. R. Bennett et al., “Antimonide-based compound semiconductors for electronic devices: A review”, Solid-State Electronics, vol. 49, pp. 1875-1895, 2005.

### SUMMARY

### Technical Problem

As described above, although the “UTC-PD” structure is conventionally effective in improving high-speed performance of light receiving devices, it is not necessarily easy to construct the “UTC-PD” structure when material such as Si/Ge-based or Sb-based material is used.

Embodiments of the present invention have been made to solve problems as described above, and an object is to allow the “UTC-PD” structure to be constructed using material such as Si/Ge-based or Sb-based material.

### Means for Solving the Problem

A light receiving device according to embodiments of the present invention comprises a first semiconductor layer made of a p-type semiconductor formed on a substrate, a second semiconductor layer made of an n-type semiconductor formed on the substrate, a carrier transit layer made of an undoped semiconductor formed between the first semiconductor layer and the second semiconductor layer, and an n-type light absorbing layer made of an n-type semiconductor formed between the second semiconductor layer and the carrier transit layer, wherein the n-type light absorbing layer has a smaller bandgap energy than other layers.

In the light receiving device, impurity concentration of the n-type light absorbing layer may be made lower as coming closer to the carrier transit layer.

In the light receiving device, the n-type light absorbing layer is made of a mixed crystal semiconductor made of two elements, and by changing a composition ratio of the two elements from a side of the carrier transit layer to a side of the second semiconductor layer, an energy level at a valence band edge of the n-type light absorbing layer on the side of the carrier transit layer may be made in a state of being located on a higher energy side compared with a case where the composition ratio is not changed.

In the light receiving device, the carrier transit layer may be composed of a first carrier transit layer disposed on the side of the first semiconductor layer and a second carrier transit layer disposed on the side of the n-type light absorbing layer, and the light receiving device may further comprise a third semiconductor layer made of a p-type semiconductor disposed between the first carrier transit layer and the second carrier transit layer.

In the light receiving device, the light receiving device may further comprise a p-type light absorbing layer made of a p-type semiconductor formed between the carrier transit layer and the second semiconductor layer.

### Effects of Embodiments of the Invention

As described above, according to embodiments of the present invention, since the carrier transit layer made of an undoped semiconductor is formed between the first semiconductor layer and the second semiconductor layer and the n-type light absorbing layer made of an n-type semiconductor is formed between the second semiconductor layer and the carrier transit layer, it is possible to obtain an excellent effect that the “UTC-PD” structure can be constructed using material such as Si/Ge-based or Sb-based material.

### BRIEF DESCRIPTION OF THE DRAWINGS

FIG. 1 is a sectional view showing a configuration of a light receiving device according to Embodiment 1 of the present invention.

FIG. 2 is a band diagram showing a band configuration of the light receiving device according to Embodiment 1 of the present invention.

FIG. 3 is a band diagram showing a band configuration of a light receiving device according to Embodiment 2 of the present invention.

FIG. 4 is a band diagram showing a band configuration of a light receiving device according to Embodiment 3 of the present invention.

FIG. 5 is a band diagram showing a band configuration of a light receiving device according to Embodiment 4 of the present invention.

FIG. 6 is a band diagram showing a band configuration of a light receiving device according to Embodiment 5 of the present invention.

### DETAILED DESCRIPTION OF ILLUSTRATIVE EMBODIMENTS

Hereinafter, light receiving devices according to embodiments of the present invention will be described.

### Embodiment 1

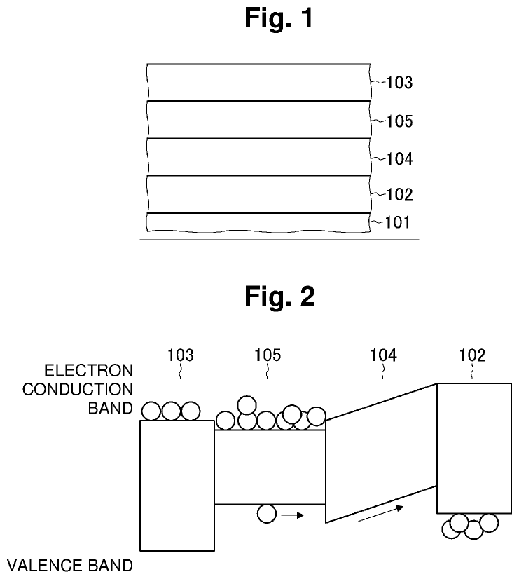

First, a light receiving device according to Embodiment 1 of the present invention will be described with reference to FIGS. 1 and 2. The light receiving device first includes a first semiconductor layer 102 made of a p-type semiconductor formed on a substrate 101, and a second semiconductor layer 103 made of an n-type semiconductor formed on the substrate 101.

The light receiving device further includes a carrier transit layer 104 made of an undoped semiconductor formed between the first semiconductor layer 102 and the second semiconductor layer 103, and an n-type light absorbing layer 105 made of an n-type semiconductor formed between the second semiconductor layer 103 and the carrier transit layer 104. Here, the n-type light absorbing layer 105 is made to have a smaller bandgap energy than other layers. In each of the first semiconductor layer 102 and the second semiconductor layer 103, an electrode (not shown) is formed in a region (not shown).

The substrate 101 is made of, for example, Si. The first semiconductor layer 102 is made of, for example, Si, and is doped with, for example, B by about 1.0×10¹⁹ cm⁻³ to be p-type. The second semiconductor layer 103 is made of, for example, Si, and is doped with, for example, P by about 1.0×10¹⁹ cm⁻³ to be n-type. The carrier transit layer 104 is made of, for example, SiGe (mixed crystal of Si and Ge). The n-type light absorbing layer 105 is made of, for example, Ge, and is doped with, for example, P by about 1.0×10¹⁹ cm⁻³ to be n-type.

Next, an operation principle of the light receiving device of Embodiment 1 will be described with reference to a band diagram of FIG. 2. When signal light enters the light receiving device of Embodiment 1, the signal light is absorbed in the n-type light absorbing layer 105, and at the same time, electron-hole pairs are photoexcited. Since the n-type light absorbing layer 105 is doped to be n-type, electrons of the generated electron-hole pairs undergo charge transfer through a dielectric relaxation process.

On the other hand, generated holes behave as minority carriers in the n-type light absorbing layer 105 and move through a diffusion process. Since diffusion motion of the holes originally exhibits random behavior, they can move toward any of the second semiconductor layer 103 and the first semiconductor layer 102. However, due to a large valence band offset between the second semiconductor layer 103 made of n-Si and the n-type light absorbing layer 105, movement of the holes in the n-type light absorbing layer 105 toward the second semiconductor layer 103 is inhibited. The holes generated in the n-type light absorbing layer 105 caused by photoexcitation reach the first semiconductor layer 102 via the carrier transit layer 104.

Since an electric field is generated in the carrier transit layer 104 under a constant voltage application condition, the holes drift in the carrier transit layer 104. As a result, in the light receiving device according to Embodiment 1, the n-type light absorbing layer 105 is made n-type to make holes minority carriers, and a conduction band edge offset of Ge and Si is made a barrier for the holes; thereby the UTC-PD can be constructed even with light receiving devices made of Si/Ge-based materials, which is difficult in the current system.

Next, a method for manufacturing the light receiving device according to Embodiment 1 will be briefly described. First, p-type Si, undoped SiGe, n-type Ge, and n-type Si are epitaxially grown in this order on the substrate 101 using a low pressure CVD (Chemical Vapor Deposition) method to form the first semiconductor layer 102, carrier transit layer 104, n-type light absorbing layer 105, and second semiconductor layer 103.

If the thickness of the n-type light absorbing layer 105 is equal to or less than 200 nm, a dramatic improvement in speed performance can be expected as compared to a general pin-type light receiving device. If Si_{0.4}Ge_{0.6} is used as the composition ratio of SiGe in the carrier transit layer 104, signal light in a communication wavelength band is not absorbed in the carrier transit layer 104, and a desired UTC-PD operation can be performed.

After crystal growth of each layer as described above, each layer is processed into a desired light receiving device shape. For example, the second semiconductor layer 103 to the first semiconductor layer 102 are processed into a circular mesa shape by dry etching. SF₆ may be used as an etching gas. After processing into the mesa shape, an electrode is formed at a predetermined position by depositing Au/AI by an electron beam evaporation method or the like.

As described above, it is possible to implement a high-speed light receiving device even with Si/Ge-based materials by the embodiment.

### Embodiment 2

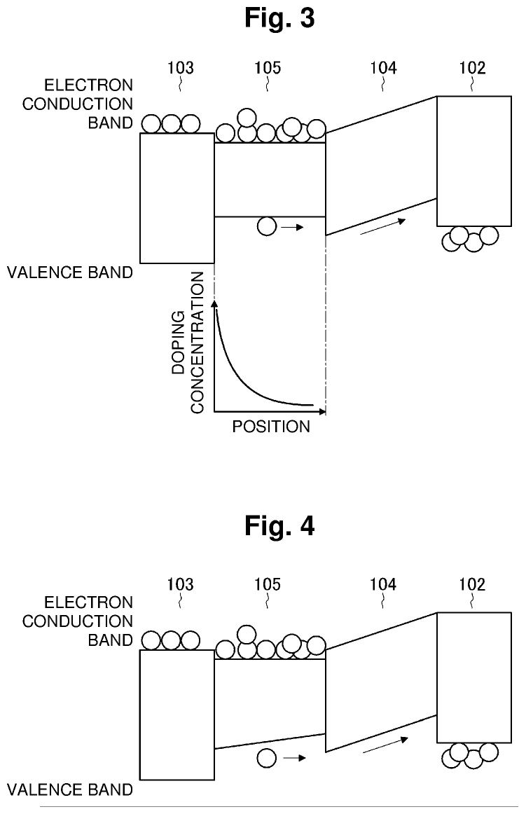

Next, Embodiment 2 of the present invention will be described with reference to FIGS. 1 and 3. A light receiving device according to Embodiment 2 first includes a first semiconductor layer 102 formed on a substrate 101, a second semiconductor layer 103 formed on the substrate 101, a carrier transit layer 104 formed between the first semiconductor layer 102 and the second semiconductor layer 103, and an n-type light absorbing layer 105 formed between the second semiconductor layer 103 and the carrier transit layer 104. The configuration is the same as that of aforementioned Embodiment 1.

In Embodiment 2, impurity concentration of the n-type light absorbing layer 105 is made smaller as coming closer to the carrier transit layer 104. The n-type light absorbing layer 105 is made of, for example, Ge, is doped with, for example, P to be n-type, and is made in a state in which the impurity concentration changes from 1.0×10¹⁹ cm⁻³ to 1.0×10¹⁶ cm⁻³.

Next, an operation principle of the light receiving device of Embodiment 2 will be described with reference to a band diagram of FIG. 3. In aforementioned Embodiment 1, the basic configuration of the light receiving device that sets holes as minority carriers has been described, in which among electron-hole pairs generated in the n-type light absorbing layer 105, electrons undergo charge transfer to the second semiconductor layer 103 through a dielectric relaxation process, and holes move to the carrier transit layer 104 through a diffusion process and further move to the first semiconductor layer 102 through a drift process in the carrier transit layer 104.

However, a carrier transit time due to the diffusion process is proportional to the square of layer thickness. Therefore, in the configuration shown in Embodiment 1, the n-type light absorbing layer 105 cannot be made thick very much.

In contrast, in Embodiment 2, the impurity concentration in the n-type light absorbing layer 105 is made lower toward the first semiconductor layer 102. According to this doping profile, the light receiving device according to Embodiment 2 generates a pseudo electric field without intentionally applying external voltage. Thereby, holes generated in the n-type light absorbing layer 105 have a drift component caused by the pseudo electric field together with a diffusion component. As a result, a hole transport time in the n-type light absorbing layer 105 becomes shorter than that of Embodiment 1, so the n-type light absorbing layer 105 can be made thicker. Thereby, without sacrificing the high-speed property of the light receiving device, higher sensitivity can be achieved.

### Embodiment 3

Next, Embodiment 3 of the present invention will be described with reference to FIGS. 1 and 4. A light receiving device according to Embodiment 3 first includes a first semiconductor layer 102 formed on a substrate 101, a second semiconductor layer 103 formed on the substrate 101, a carrier transit layer 104 formed between the first semiconductor layer 102 and the second semiconductor layer 103, and an n-type light absorbing layer 105a formed between the second semiconductor layer 103 and the carrier transit layer 104. The first semiconductor layer 102, second semiconductor layer 103, and carrier transit layer 104 are the same as those of aforementioned Embodiment 1.

In Embodiment 3, first, the n-type light absorbing layer 105a is made of a mixed crystal semiconductor made of at least two elements. For example, the n-type light absorbing layer 105a is made of SiGe. In addition, by changing a composition ratio of the two elements forming the n-type light absorbing layer 105a from a side of the carrier transit layer 104 to a side of the second semiconductor layer 103, an energy level at a valence band edge of the n-type light absorbing layer 105a on the side of the carrier transit layer 104 is made in a state of being located on a higher energy side as compared with a case where the composition ratio is not changed. For example, the composition ratio of Ge is made higher as coming closer to the carrier transit layer 104.

As described above, in Embodiment 1, among electron-hole pairs generated in the n-type light absorbing layer 105, electrons undergo charge transfer to the second semiconductor layer 103 through a dielectric relaxation process, holes move to the carrier transit layer 104 through a diffusion process and further move to the first semiconductor layer 102 through a drift process in the carrier transit layer 104. In this way, in Embodiment 1, the light receiving device that sets holes as minority carriers has been described.

However, the carrier transit time due to the diffusion process is proportional to the square of layer thickness. Therefore, in the light receiving device of Embodiment 1, the n-type light absorbing layer 105 cannot be made thick very much. In contrast, in Embodiment 3, the n-type light absorbing layer 105a is made of SiGe and the Ge composition is made to increase toward the carrier transit layer 104. Regarding the mixed crystal of Si and Ge, an energy level of a conduction band edge does not largely change in all composition ratios. However, regarding the mixed crystal of Si and Ge, an energy level at a valence band edge largely changes to a maximum of 0.5 eV depending on the composition ratio. In the mixed crystal of Si and Ge, the larger the Ge composition ratio is, the higher energy side the energy level at the valence band edge is located on.

According to the above-described energy profile of the valence band edge, the light receiving device of Embodiment 3 generates a pseudo electric field without intentionally applying external voltage. Thereby, holes generated in the n-type light absorbing layer 105a has a drift component caused by the pseudo electric field together with a diffusion component. As a result, a hole transport time in the n-type light absorbing layer 105a can be made shorter than that in Embodiment 1, so the n-type light absorbing layer 105a can be made thicker. Thereby, according to the light receiving device according to Embodiment 3, without sacrificing the high-speed property, higher sensitivity can be achieved.

A method for manufacturing the light receiving device according to Embodiment 3 will be briefly described. First, p-type Si and undoped SiGe are epitaxially grown in this order on the substrate 101 using the low pressure CVD method to form the first semiconductor layer 102 and the carrier transit layer 104.

Next, in Embodiment 3, when a source gas of Ge and a source gas of Si are supplied to grow n-type SiGe to from the n-type light absorbing layer 105a, the supply amount of the Ge source gas is reduced over time and the supply amount of the Si source gas is increased at the same time. A dopant is P, and impurity concentration may be equal to or more than 1.0×10¹⁸ cm⁻³. Then, n-type Si is epitaxially grown to form the second semiconductor layer 103 on the n-type light absorbing layer 105a. Hereafter, an element shape and an electrode are formed by a device manufacturing process the same as that of aforementioned Embodiment 1.

Regarding the n-type light absorbing layer 105a, needless to say, it is advantageous to a higher sensitivity operation if the range of a composition change of the mixed crystal is set to a bandgap (Si composition is about 20% or less in a 1.3 μm band) enough to absorb signal light in the communication wavelength band even in composition giving the maximum bandgap.

By the structure described above, higher sensitivity can be achieved without sacrificing the high speed property of the light receiving device. Note that in Embodiment 3 described above, the case of forming the n-type light absorbing layer 105a from SiGe has been described, but the present invention is not limited to this. For example, when a light receiving device is made of an In-based or a Ga-based compound semiconductor, the same applies to a case where the n-type light absorbing layer 105a is made of InAsSb, GaAsSb, or InGaAsSb, and a composition ratio of Sb having a higher atomic weight of elements in a higher group is increased toward the carrier transit layer 104 with respect to a composition ratio of As having a lower atomic weight.

### Embodiment 4

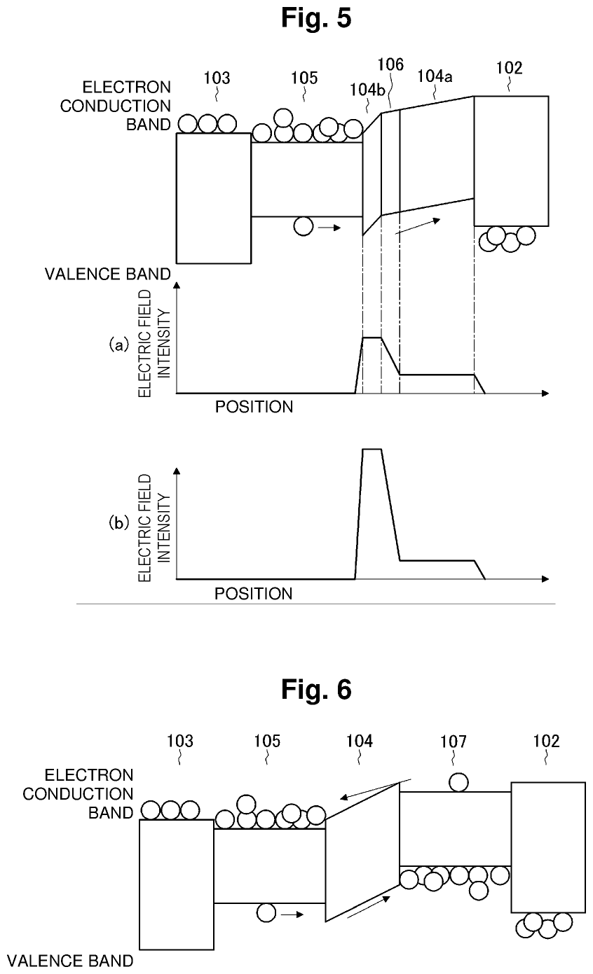

Next, Embodiment 4 of the present invention will be described with reference to FIG. 5. In Embodiment 4, first, the carrier transit layer 104 of the light receiving device according to aforementioned Embodiment 1 is composed of a first carrier transit layer 104a disposed on a side of a first semiconductor layer 102 and a second carrier transit layer 104b disposed on a side of an n-type light absorbing layer 105. In addition, in Embodiment 4, a third semiconductor layer 106 made of a p-type semiconductor is disposed between the first carrier transit layer 104a and the second carrier transit layer 104b.

The light receiving device of Embodiment 1 uses diffusion movement of holes in the n-type light absorbing layer 105 to obtain a high-speed and high-sensitivity operation of the light receiving device. When the light receiving device is made of a Si/Ge-based material like Embodiment 1, there is a concern that holes may not be injected into the carrier transit layer 104 due to a valence band edge offset generated at an interface between the n-type light absorbing layer 105 and the carrier transit layer 104. Although increasing an application voltage of the light receiving device increases electric field intensities of the carrier transit layer 104 and the interface between the n-type light absorbing layer 105 and the carrier transit layer 104 and eliminates this concern, another concern of an increased operation voltage occurs.

In the embodiment, by inserting the third semiconductor layer 106 (p-type electric field control layer) with appropriate impurity concentration and layer thickness into the carrier transit layer 104, a high electric field intensity is selectively provided at the interface between the n-type light absorbing layer 105 and the carrier transit layer 104 as shown in (a) and (b) of FIG. 5. When a voltage is applied to the light receiving device of the embodiment in a reverse direction from 0 V, depletion of the n-type light absorbing layer 105 and the third semiconductor layer 106 progresses, and the electric field intensity of the second carrier transit layer 104b portion sandwiched between both layers increases as shown in (a) to (b) of FIG. 5.

At a certain voltage, the third semiconductor layer 106 is completely depleted, and an electric field is also generated in the first carrier transit layer 104a, a region sandwiched between the third semiconductor layer 106 and the first semiconductor layer 102. In this state, holes injected into the carrier transit layer 104 (second carrier transit layer 104b) drift, which enables a high-speed operation.

According to the embodiment, since a high electric field intensity is selectively applied to a narrow portion of an interface between the n-type light absorbing layer 105 and the second carrier transit layer 104b, an application voltage necessary for the operation of the light receiving device is not large. In other words, as compared with Embodiment 1, a high electric field intensity can be applied to the interface portion between the n-type light absorbing layer 105 and the second carrier transit layer 104b at a lower voltage.

According to Embodiment 4, the light receiving device can also be applied as an avalanche photodiode capable of a higher sensitivity operation but not just as a photodiode. Since a complete depletion voltage of the third semiconductor layer 106 depends on a product of the impurity concentration and the film thickness of the third semiconductor layer 106, increasing the product increases a voltage at which the third semiconductor layer 106 is completely depleted. At this time, the electric field intensity of the second carrier transit layer 104b sandwiched between the n-type light absorbing layer 105 and the third semiconductor layer 106 locally increases until the voltage at which the third semiconductor layer 106 is completely depleted. By increasing the electric field intensity of the second carrier transit layer 104b to an electric field intensity required for avalanche multiplication, the light receiving device of Embodiment 4 operates as an avalanche photodiode.

Next, a method for manufacturing the light receiving device according to Embodiment 4 will be briefly described. First, p-type Si and undoped SiGe are epitaxially grown in this order on the substrate 101 using the low pressure CVD method to form the first semiconductor layer 102 and the first carrier transit layer 104a. Following the formation of the first carrier transit layer 104a, a source gas of B serving as a P-type dopant in addition to a source gas of Si and a source gas of Ge is introduced to from the third semiconductor layer 106. Subsequently, the introduction of the source gas of B is stopped to form the second carrier transit layer 104b. Hereafter, n-type Ge and n-type Si are epitaxially grown in this order to form the n-type light absorbing layer 105 and the second semiconductor layer 103.

When the light receiving device according to Embodiment 4 is operated as a photodiode, for example, the first carrier transit layer 104a may be 200 nm in thickness, the third semiconductor layer 106 may be 1×10¹⁷ cm⁻³ in doping concentration and 50 nm in thickness, and the second carrier transit layer 104b may be 50 nm in thickness.

When the light receiving device according to Embodiment 4 is operated as an avalanche photodiode, the first carrier transit layer 104a may be 150 nm in thickness, the third semiconductor layer 106 may be 8×10¹⁷ cm⁻³ in doping concentration and 50 nm in thickness, and the second carrier transit layer 104b may be 100 nm in thickness.

By the configuration described above, according to Embodiment 4, a low voltage operation of the light receiving device can be achieved in addition to the higher speed and higher sensitivity. In addition, an avalanche diode enabling a high-sensitivity operation can be implemented.

### Embodiment 5

Next, Embodiment 5 of the present invention will be described with reference to FIG. 6. A light receiving device according to Embodiment 5 first includes a first semiconductor layer 102 made of a p-type semiconductor and a second semiconductor layer 103 made of an n-type semiconductor formed on a substrate.

The light receiving device further includes a carrier transit layer 104 made of an undoped semiconductor formed between the first semiconductor layer 102 and the second semiconductor layer 103, and an n-type light absorbing layer 105 made of an n-type semiconductor formed between the second semiconductor layer 103 and the carrier transit layer 104.

In Embodiment 5, the light receiving device further includes a p-type light absorbing layer 107 made of a p-type semiconductor between the carrier transit layer 104 and the second semiconductor layer 103. The n-type light absorbing layer 105 is made to have a smaller bandgap energy than other layers. In each of the first semiconductor layer 102 and the second semiconductor layer 103, an electrode (not shown) is formed in a region (not shown).

In Embodiment 5, the p-type light absorbing layer 107 is added to the configuration of Embodiment 1. Each layer is made of Si and Ge in Embodiment 1, but the present invention is not limited to this. Embodiment 5 will be described taking a case of forming from the group III-V compound semiconductor as an example.

For example, the second semiconductor layer 103 is made of an n-type GaAs substrate, and the n-type light absorbing layer 105 is made of InGaSb and is doped with, for example, Si by 1.0×10¹⁸ cm⁻³ or more to be n-type. The carrier transit layer 104 is made of undoped GaAs, and the p-type light absorbing layer 107 is made of InGaAs and is doped with, for example, Be by 1.0×10¹⁸ cm⁻³ or more to be p-type. The first semiconductor layer 102 is made of GaAs and is doped with, for example, Be by 1.0×10¹⁹ cm⁻³ or more to be p-type.

Next, an operation principle of the light receiving device of Embodiment 5 will be described with reference to a band diagram of FIG. 6. The light receiving device in Embodiment 5 further includes the p-type light absorbing layer 107 in addition to the aforementioned embodiment. In Embodiment 5, the carrier transit layer 104 is provided between the two light absorbing layers.

In Embodiment 5, behavior of carriers photoexcited in the n-type light absorbing layer 105 is the same as that of the aforementioned embodiment, and holes diffuse and move as effective carriers, drift in the carrier transit layer 104, and then undergo dielectric relaxation in the p-type light absorbing layer 107. Here, InGaSb forming the n-type light absorbing layer 105 is known for its particularly high hole mobility among group III-V semiconductors (see Non-Patent Literature 4). Therefore, forming the n-type light absorbing layer 105 from InGaSb is suitable for higher speed and higher sensitivity as a light receiving device.

On the other hand, the p-type light absorbing layer 107 is made of InGaAs having a high electron mobility. Electrons generated in the p-type light absorbing layer 107 by light reception diffuse and move, then drift in the carrier transit layer 104, and undergo dielectric relaxation in the n-type light absorbing layer 105.

To summarize the carrier movement involved in the two types of light absorbing layers described above, the thickness of the p-type light absorbing layer 107 does not affect the transport time of holes generated in the n-type light absorbing layer 105, and the thickness of the n-type light absorbing layer 105 does not affect electrons generated in the p-type light absorbing layer 107. Consequently, the thickness of the two light absorbing layers can be designed independently of each other from the viewpoint of carrier transport speed. On the other hand, light receiving sensitivity of the light receiving device of Embodiment 5 is determined by the total thickness of the two types of light absorbing layers described above. As a result, according to Embodiment 5, higher sensitivity can be achieved even at the same operation speed as compared with the case of forming from one light absorbing layer.

Next, a method for manufacturing the light receiving device according to Embodiment 5 will be briefly described. First, n-type InGaSb, undoped GaAs, p-type InGaAs, and p-type GaAs are epitaxially grown in this order on an n-type GaAs substrate using, for example, a molecular beam epitaxy (MBE) method to form the second semiconductor layer 103, n-type light absorbing layer 105, carrier transit layer 104, p-type light absorbing layer 107, and first semiconductor layer 102. Note that there is a case where epitaxial growth is difficult from the viewpoint of lattice matching depending on the mixed crystal composition ratio of each layer. In such a case, the stacked state of each layer described above may be obtained by a wafer bonding technique.

After forming each layer as described above, each layer is processed into a desired light receiving device shape. For example, the first semiconductor layer 102 to the second semiconductor layer 103 are processed into a circular mesa shape by dry etching. SF₆ may be used as an etching gas. After processing into the mesa shape, an electrode is formed at a predetermined position by depositing Au/AI by an electron beam evaporation method or the like. By the configuration described above, higher speed and higher sensitivity of the light receiving device can be achieved.

As described above, according to embodiments of the present invention, the carrier transit layer made of an undoped semiconductor is formed between the first semiconductor layer and the second semiconductor layer, and the n-type light absorbing layer made of an n-type semiconductor is formed between the second semiconductor layer and the carrier transit layer, so the “UTC-PD” structure can be constructed using material such as on Si/Ge-based or Sb-based material.

Note that the present invention is not limited to the embodiments described above, it is obvious that many modifications and combinations can be made by those having ordinary knowledge in the art within the technical idea of the invention. For example, the light receiving devices in Embodiments 1-4 may be made of the group III-V compound semiconductors as in Embodiment 5. Embodiment 5 has been described with an example of using the group III-V compound semiconductor, but it is not limited to this, and may be made of Si and Ge as in Embodiments 1-4. For example, the p-type light absorbing layer may be made of Ge that is made p-type by doping B.

### REFERENCE SIGNS LIST

101 Substrate

102 First semiconductor layer

103 Second semiconductor layer

104 Carrier transit layer

105 N-type light absorbing layer.

1.-5. (canceled)

6. A light receiving device, comprising:
a first semiconductor layer made of a p-type semiconductor on a substrate;
a second semiconductor layer made of an n-type semiconductor on the substrate;
a carrier transit layer made of an undoped semiconductor between the first semiconductor layer and the second semiconductor layer; and
an n-type light absorbing layer made of an n-type semiconductor between the second semiconductor layer and the carrier transit layer, wherein the n-type light absorbing layer has a smaller bandgap energy than the first semiconductor layer, the second semiconductor layer, and the carrier transit layer.

7. The light receiving device according to claim 6, wherein an impurity concentration of the n-type light absorbing layer decreases in a direction towards the carrier transit layer.

8. The light receiving device according to claim 6, wherein the n-type light absorbing layer is a mixed crystal semiconductor made of two elements.

9. The light receiving device according to claim 8, wherein by changing a composition ratio of the two elements from a side of the carrier transit layer to a side of the second semiconductor layer, an energy level at a valence band edge of the n-type light absorbing layer on the side of the carrier transit layer is higher energy compared with where the composition ratio is not changed.

10. The light receiving device according to claim 6, wherein:
the carrier transit layer comprises a first carrier transit layer disposed on a side of the first semiconductor layer and a second carrier transit layer disposed on a side of the n-type light absorbing layer; and
the light receiving device further comprises a third semiconductor layer made of a p-type semiconductor between the first carrier transit layer and the second carrier transit layer.

11. The light receiving device according to claim 6, further comprising a p-type light absorbing layer made of a p-type semiconductor between the carrier transit layer and the second semiconductor layer.

12. A method, comprising:
forming a first semiconductor layer made of a p-type semiconductor on a substrate;
forming a second semiconductor layer made of an n-type semiconductor on the substrate;
forming a carrier transit layer made of an undoped semiconductor between the first semiconductor layer and the second semiconductor layer; and
forming an n-type light absorbing layer made of an n-type semiconductor between the second semiconductor layer and the carrier transit layer, wherein the n-type light absorbing layer has a smaller bandgap energy than the first semiconductor layer, the second semiconductor layer, and the carrier transit layer.

13. The method according to claim 12, wherein forming the n-type light absorbing layer comprises forming an impurity concentration of the n-type light absorbing layer to decrease in a direction towards the carrier transit layer.

14. The method according to claim 12, wherein forming the n-type light absorbing layer comprises forming a mixed crystal semiconductor made of two elements.

15. The method according to claim 14, wherein forming the n-type light absorbing layer comprises changing a composition ratio of the two elements from a side of the carrier transit layer to a side of the second semiconductor layer so that an energy level at a valence band edge of the n-type light absorbing layer on the side of the carrier transit layer is higher energy compared with when the composition ratio is not changed.

16. The method according to claim 12, wherein
forming the carrier transit layer comprises forming a first carrier transit layer on a side of the first semiconductor layer and forming a second carrier transit layer on a side of the n-type light absorbing layer; and
the method further comprises forming a third semiconductor layer made of a p-type semiconductor between the first carrier transit layer and the second carrier transit layer.

17. The method according to claim 12, further comprising forming a p-type light absorbing layer made of a p-type semiconductor between the carrier transit layer and the second semiconductor layer.
